(19) United States
(12) Patent Application Publication
(10) Pub. No.: US 2009/0148977 A1
(43) Pub. Date: Jun. 11, 2009

(54) PACKAGING METHOD FOR IMAGE SENSOR IC

(76) Inventor: Jack Ting, Sanchung City (TW)

Correspondence Address: LEONG C LEI, PMB # 1008, 1867 YGNACIO VALLEY ROAD, WALNUT CREEK, CA, 94598, US

(21) Appl. No.: 11/964,052

(22) Filed: Dec. 26, 2007

(30) Foreign Application Priority Data
Dec. 5, 2007 (TW) 096146357

(51) Int. Cl. H01L 21/00

(52) U.S. Cl. 438/66; 257/E21.001

(57) ABSTRACT

The method contains the following steps. First, a number of circuit blocks are formed in one or more tightly populated array on an uncut substrate. The substrate is then placed on a flat platform where a number of pins on the platform threading through corresponding holes of the substrate. A number of image sensor ICs are then fixed on the circuit blocks, respectively, and the ICs are wire-bonded to their underlying circuit blocks. Subsequently, gaps between the ICs are filled with an adhesive until the adhesive is slightly over a top side of the ICs. An uncut filtering glass is placed on the adhesive and the pins of the platform before the adhesive is thermally cured. To separate packaged image sensor IC modules, cutting is performed in the middle of the cured adhesive between two adjacent rows and columns of ICs.

### (a) TECHNICAL FIELD OF THE INVENTION

The present invention generally relates to IC packaging methods, and more particularly to a method that sandwiches multiple image sensor ICs between an uncut filtering glass and an uncut substrate before separating them into packaged modules by a reduced amount of cutting.

### (b) DESCRIPTION OF THE PRIOR ART

Image sensor IC (integrated circuit) is a key component for digital cameras. As it is continuously driven to be even smaller so as to fit on various handheld consumer electronic devices, the packaging of image sensor ICs has become a delicate art. The one who consumes less material and requires less working time in packaging image sensor ICs would enjoy a competitive edge against fellow manufacturers.

A common packaging process for image sensor ICs is depicted in the flow chart of FIG. 1 and the product of the process is shown in FIG. 2. As illustrated, a number of image sensor ICs 10 are first fixed to an uncut substrate 50. Wire bonding is then conducted to electrically connect the image sensor ICs 10 to the circuit blocks (not shown) of the substrate 50 with bonding wires 11. Subsequently, a filtering glass 30 already cut to an appropriate size is adhered to a top side of each IC 10 by adhesive 20. Adhesive 40 is then applied and thermally cured to seal the ICs 10 and their respective filtering glasses 30. Finally, the entire assembly is cut to produce separate packaged image sensor IC modules. The foregoing process has a number of shortcomings. First, to prepare the filtering glasses 30, a large piece of filtering glass has to be precisely cut and each individual filtering glass 30 has to be adhered to an IC 10. This is a time-consuming, laborious, and therefore costly process. The subsequent cutting of the substrate implies an additional cutting process and, therefore, an increase of cutting cost.

To facilitate cutting and separating the individual packaged image sensor IC module, an appropriate gap has to be reserved between them, implying some portion of the substrate 50 has to be sacrificed and wasted. Furthermore, to separate two adjacent rows or columns of image sensor IC modules, two cutting operations have to be performed along the gap, so that there is no extraneous margin attached to each image sensor IC module. This means that the cutting effort is not necessarily doubled.

Another common packaging process for image sensor ICs is depicted in the flow chart of FIG. 3 and the product of the process is shown in FIG. 4. As illustrated, plastic frames 70 are prepared on an uncut substrate 90 in advance. The image sensor ICs 60 are then adhered to the substrate 90 within the plastic frames 70, respectively Wire bonding is subsequently conducted to electrically connect the image sensor ICs 60 to the circuit blocks (not shown) of the substrate 90 with bonding wires 61. Adhesive 80 is coated on a top side of the plastic frames 70 before filtering glasses 81 already cut to an appropriate size are placed on the plastic frames 70, respectively. The entire assembly is then thermally cured so that each image sensor IC 60 is securely sealed. Finally, the entire assembly is cut to separate individual packaged image sensor IC modules. The foregoing process has the same shortcomings as the previous approach.

### SUMMARY OF THE INVENTION

Accordingly, a novel method for packaging image sensor ICs is provided herein that can achieve a reduced amount of cutting and a significant saving of wasted materials.

The method contains the following steps. First, a number of independent circuit blocks are formed in one or more tightly populated array on an uncut substrate. The substrate is then placed and fixed on a flat platform where a number of pins on the platform threading through corresponding holes of the substrate. A number of image sensor ICs are then placed and fixed on the circuit blocks of the substrate, respectively, and the ICs are wire-bonded to their underlying circuit blocks. Subsequently, gaps between the image sensor ICs are filled with an adhesive until the adhesive is slightly over a top side of the image sensor ICs. An uncut filtering glass is placed on the adhesive and the pins of the platform before the adhesive is thermally cured. To separate packaged image sensor IC modules, cutting is performed in the middle of the cured adhesive between two adjacent rows and columns of ICs.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a flow chart showing the steps of a conventional packaging method for image sensor ICs.

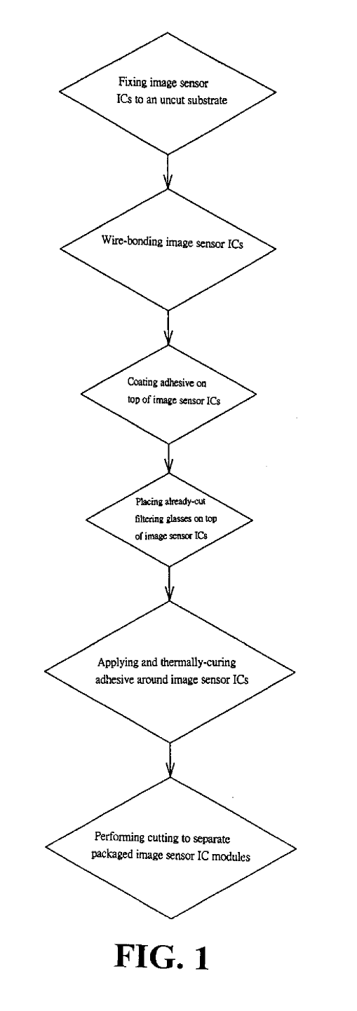

FIG. 2 is a sectional diagram showing a packaged image sensor IC module after the steps of FIG. 1.

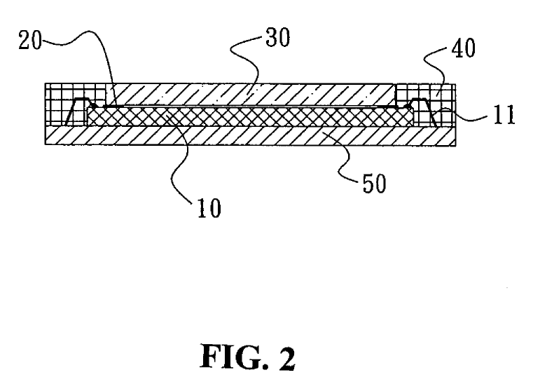

FIG. 3 is a flow chart showing the steps of another conventional packaging method for image sensor ICs.

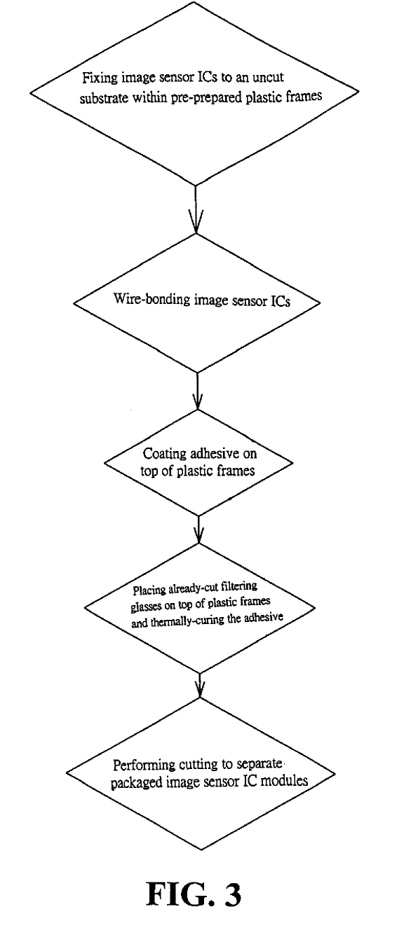

FIG. 4 is a sectional diagram showing a packaged image sensor IC module after the steps of FIG. 3.

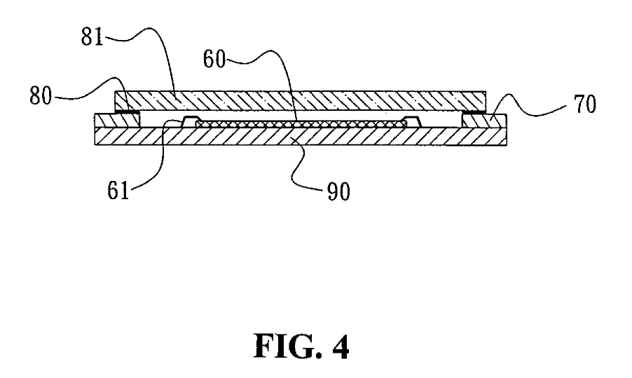

FIG. 5 is a flow chart showing the steps of a packaging method for image sensor ICs according to an embodiment of the present invention.

FIG. 6 is a perspective diagram showing an implementation environment of the method of FIG. 5.

FIG. 7 is a sectional diagram showing a packaged image sensor IC module after the steps of FIG. 5.

FIG. 8 is a sectional diagram showing a packaged image sensor IC module employed in a camera module.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

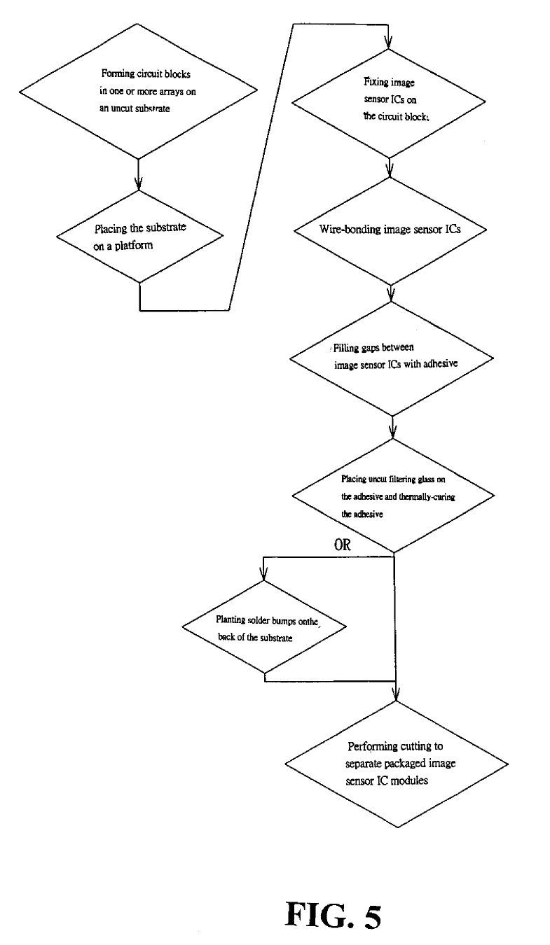

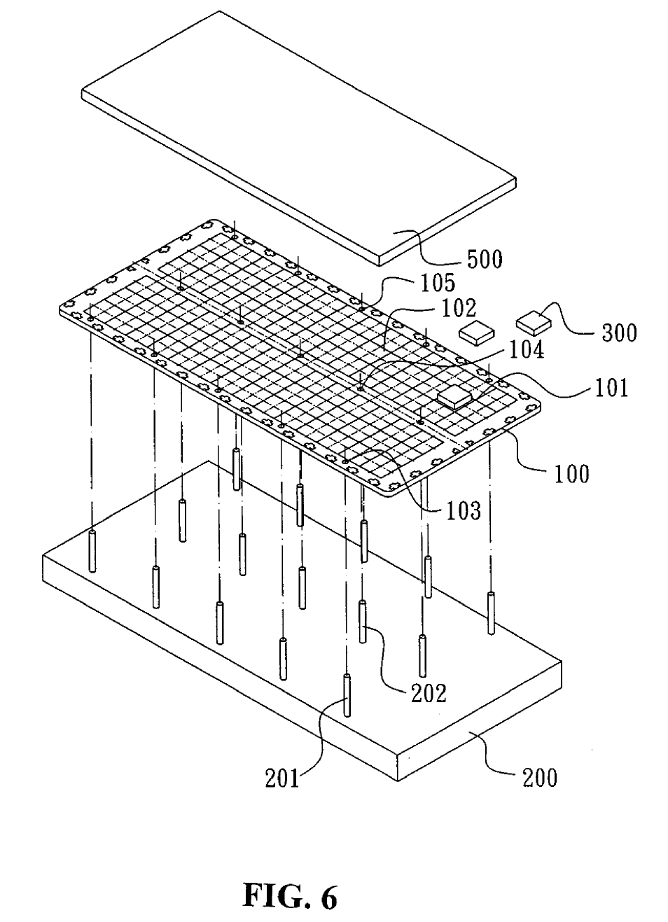

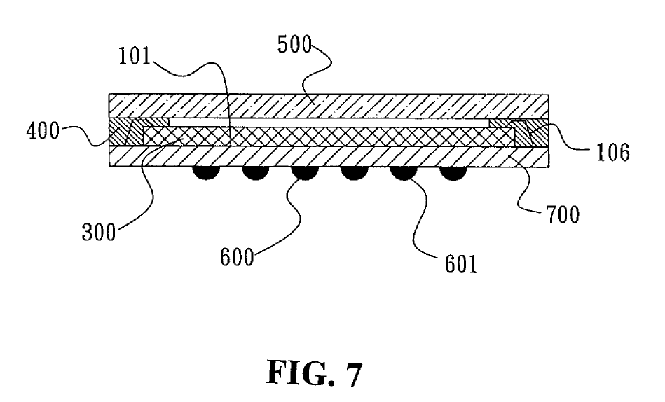

A packaging method for image sensor ICs according to an embodiment of the present invention is depicted in the flow chart of FIG. 5 whereas a tool for the packaging is shown in FIG. 6 and the product of the process is shown in FIG. 7.

As illustrated, the method contains the following steps. First, a number of independent circuit blocks 101 and 102 are formed in one or more tightly populated array on an uncut substrate 100. A number of through positioning holes 103, 104, and 105 are provided outside the arrays.

A platform 200 having a flat body and a number of vertical pins 201 and 202 on a top side is provided. The substrate 100 is placed and fixed on the top side of the platform 200 as the pins 201 and 202 are threaded trough the positioning holes 103, 104, and 105 of the substrate 100.

A number of image sensor ICs 300 are then placed and fixed on a top side of the circuit blocks 101 and 102, respectively. As each circuit block 101 or 102 is slightly larger than the IC 300, a gap is formed among adjacent ICs 300. Each of the ICs 300 is then electrically connected to an underlying circuit block 101 or 102 by bonding wires 106. Adhesive 400 is then applied to fill up the gaps between the ICs 300 until the adhesive 400 is slightly over a top side of the ICs 300.

Then a piece of uncut filtering glass 500 is placed upon the adhesive 400 and the pins 201 and 202. The adhesive 400 is then thermally cured. To separate packaged image sensor IC modules 700 as shown in FIG. 7, cutting is performed in the middle of the cured adhesive 400 between two adjacent rows and columns of ICs 300. Please note that, according to the present invention, only a single cut is required to separate two adjacent rows or columns of ICs, instead of two cuts as required by the prior art.

If required, an additional step could be performed to plant solder bumps 600 and 601 to a bottom side of the substrate 100 before cutting. Each individual image sensor IC module 700 after cutting is illustrated in FIG. 7.

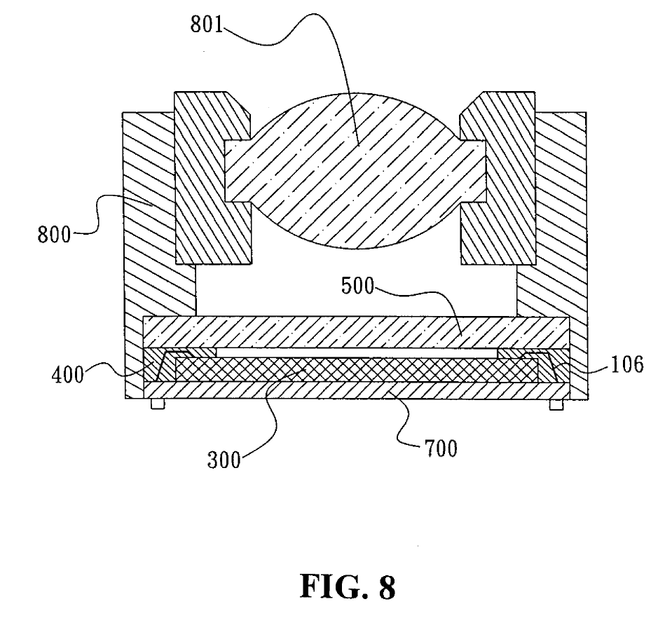

The image sensor IC module 700 then could be put through a testing process to make sure it functions correctly. Finally, the image sensor IC module 700 is used in the assembly of a camera module 800, by placing the image sensor IC module 700 at an appropriate location behind a lens 801, as illustrated in FIG. 8.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A method for packing image sensor ICs, comprising the steps of
forming a plurality of independent circuit blocks in at least a tightly populated array along a top side of an uncut substrate, said substrate having a plurality of through positioning holes outside said array;
placing said substrate on a top side of a platform, said platform having a plurality of vertical pins that threads through said positioning holes, respectively;
fixing a plurality of image sensor ICs on a top side of said circuit blocks of said substrate, respectively, thereby forming a plurality of gaps therebetween;
wire-bonding each image sensor IC to a circuit block underlying said image sensor IC;
filling said gaps with an adhesive until said adhesive is slightly over a top side of said the image sensor ICs;
placing an uncut filtering glass on said adhesive and said pins of said platform;
thermally curing said adhesive; and
producing a plurality of image sensor IC modules by performing cutting between two adjacent rows and columns of said array of said image sensor ICs.
